(19) United States
(12) Patent Application Publication
(10) Pub. No.: US 2014/0063697 A1
(43) Pub. Date: Mar. 6, 2014

(54) ELECTRONIC DEVICE WITH DETACHABLE MODULE

(71) Applicant: HAI-QING ZHOU, Shenzhen City (CN)

(72) Inventor: HAI-QING ZHOU, Shenzhen City (CN)

(21) Appl. No.: 13/629,513

(22) Filed: Sep. 27, 2012

(30) Foreign Application Priority Data
Aug. 31, 2012 (CN) 2012103176251

(51) Int. Cl. H05K 5/02

(52) U.S. Cl. 361/679.01

(57) ABSTRACT

An electronic device includes an enclosure and a detachable module. The enclosure includes a positioning wall and a positioning pin protruding in from a first end of the positioning wall. The detachable module includes a side plate parallel to the positioning wall, a latching member rotatably mounted to the side plate, and a resilient member fixed to the latching member to resiliently abut the side plate. A latching block extends down from a distal end of the latching member. The latching block includes a guiding surface on a bottom of the latching block and an engaging surface. The detachable module is inserted into the enclosure from a second end of the positioning wall. The guiding surface slides along the positioning pin, to allow the latching member to rotate, deforming the resilient member, until the engaging surface abuts the positioning pin.

### BACKGROUND

1. Technical Field

The present disclosure relates to an electronic device having a detachable module.

2. Description of Related Art

In electronic devices, such as computers or servers, there are some modules, such as power modules that are usually fixed in enclosures of the electronic devices by screws. However, it is time-consuming and often difficult to disassemble those modules from the electronic device when they need to be replaced. Therefore it would be desirable that such modules are detachably assembled to the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of an embodiment of an electronic device, wherein the electronic device includes a detachable module.

FIG. 2 is a partial, exploded, and isometric view of the detachable module of FIG. 1.

FIG. 3 is similar to FIG. 2, but viewed from another perspective.

FIG. 4 is an assembled, isometric view of the electronic device of FIG. 1.

FIG. 5 is similar to FIG. 4, but shows the electronic device in use.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

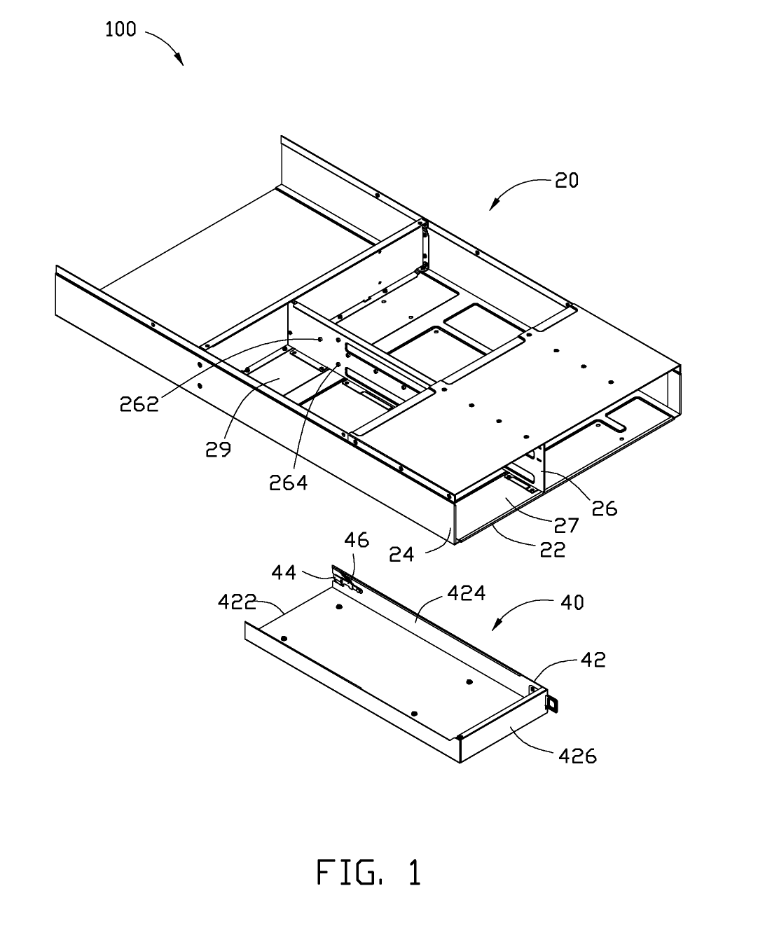

FIG. 1 shows an embodiment of an electronic device 100. The electronic device 100 includes an enclosure 20 and a detachable module 40. A plurality of components (not shown), such as a motherboard and storage apparatus, are installed in the enclosure 20. In the embodiment, the enclosure 20 is a server chassis.

The enclosure 20 includes a rectangular bottom wall 22, a sidewall 24 perpendicularly extending up from a side of the bottom wall 22, and a positioning wall 26 mounted on the bottom wall 22 and parallel to the sidewall 24. The bottom wall 22, the sidewall 24, and the positioning wall 26 cooperatively bound a receiving space 29. An inlet 27 of the receiving space 29 is located at an end of the enclosure 20. A plurality of guiding pins 262 extend into the receiving space 29 from a middle of the positioning plate 26, and is arrayed in one row parallel to the bottom wall 22. A positioning pin 264 extends into the receiving space 29 from the positioning plate 26, between the guiding pins 262 and the bottom wall 22, and away from the inlet 27.

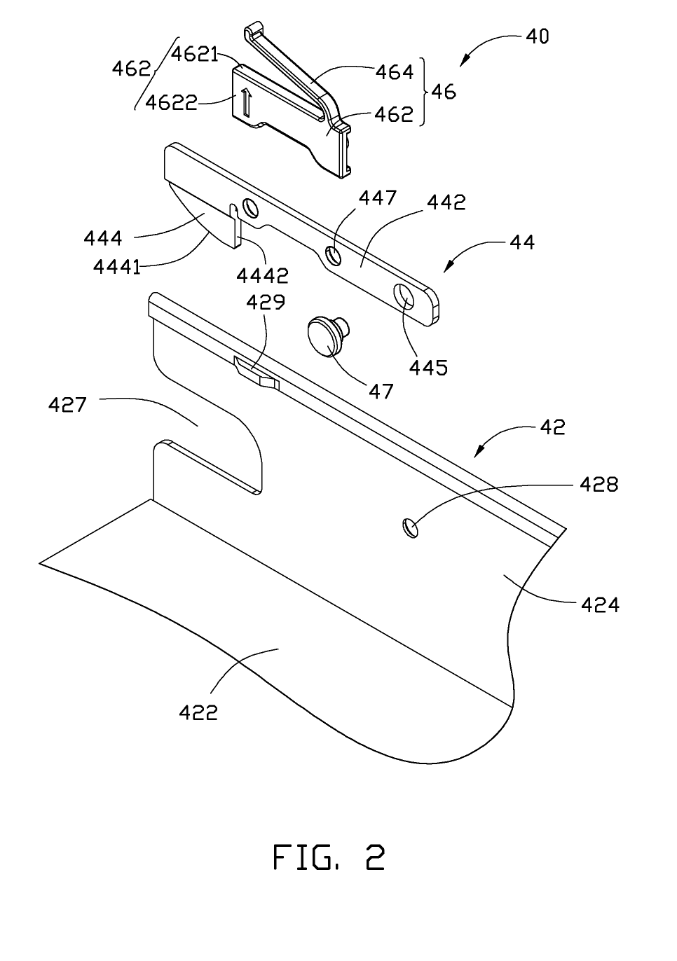

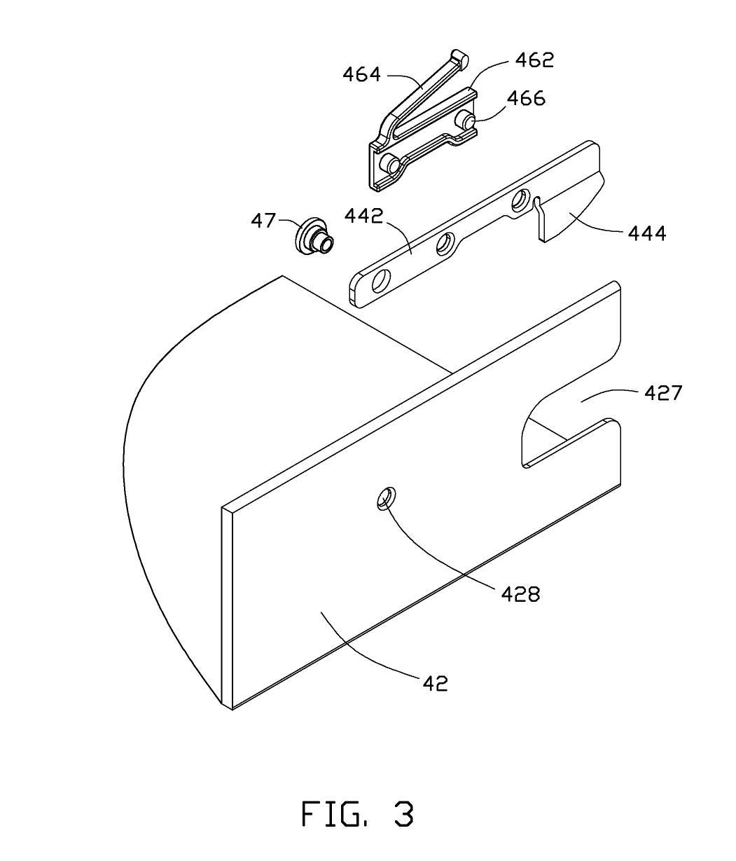

Referring to FIG. 2 and FIG. 3, the detachable module 40 includes a chassis 42, a latching member 44, and a resilient member 46.

The chassis 42 includes a rectangular bottom plate 422, two side plates 424 perpendicularly extending up from two opposite sides of the bottom plate 422, and an end plate 426 perpendicularly extending up from an end of the bottom plate 422. An end of one side plate 424 opposite to the end plate 426 defines a long cutout 427 extending along a lengthwise direction of the side plate 424, and defines a screw hole 428 located at a blind end of the cutout 427. A protrusion 429 protrudes in from the end of the side plate 424, and is located above the cutout 427.

The latching member 44 includes a rotating bar 442 and a latching block 444 extending down from a first end of the rotating bar 442. A second end of the rotating bar 442 opposite to the latching block 444 defines a rotation hole 445. The rotating bar 442 defines two latching holes 447 between the latching block 444 and the rotation hole 445. An arc-shaped guiding surface 4441 is formed on a bottom side of the latching block 444, extending down from the second end of the rotating bar 442 toward the rotation hole 445. An upright engaging surface 4442 is formed an inner side of the latching block 444 facing the rotation hole 445.

The resilient member 46 includes a base 462 and a resilient finger 464. The base 462 has a substantially U-shaped cross section, and includes a substantially rectangular connecting plate 4622, two flanges 4621 perpendicularly protruding from two opposite sides of the connecting plate 4622 toward the same direction, and two latching pins 466 extending from the connecting plate 4622 in a same direction with the flanges 4621. The finger 464 slantingly extends up from an end of a top flange 4621.

In assembly of the detachable module 40, the middle of the latching member 44 is received in the resilient member 46. The latching pins 466 are respectively latched into the latching holes 447. The latching member 44 is located at an inner surface of the side plate 424 adjacent to the cutout 427, and sandwiched between the side plate 424 and the resilient member 46. The screw 47 extends through the rotation hole 445, to screw in the screw hole 428. The latching member 44 can be rotated about the screw 47. The latching block 444 engages with the inner surface of the side plate 424, and the guiding surface 4441 faces the bottom plate 422. A distal end of the resilient finger 464 can resiliently abut a bottom of the protrusion 429.

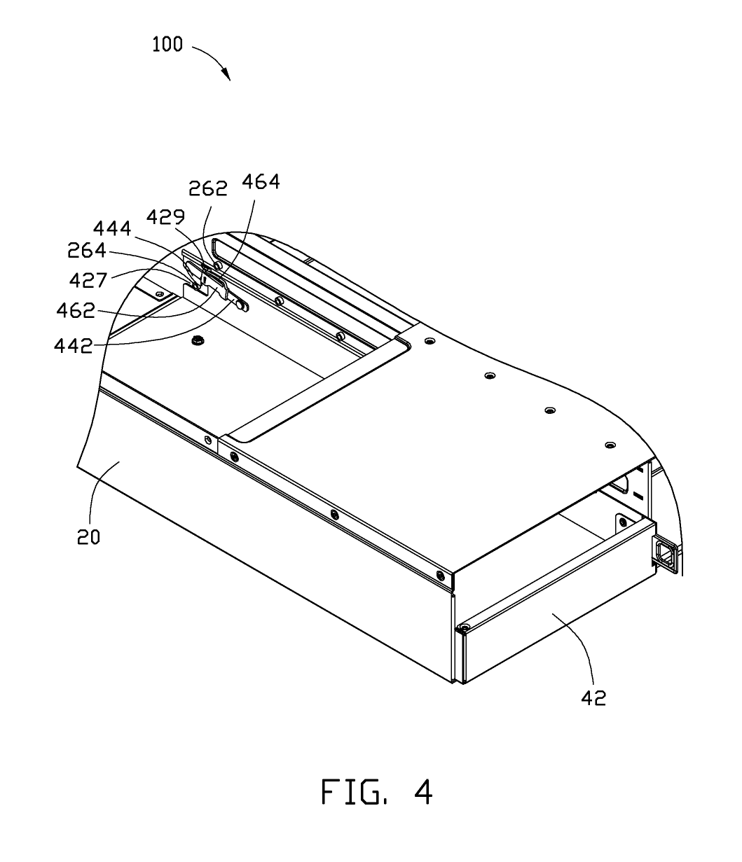

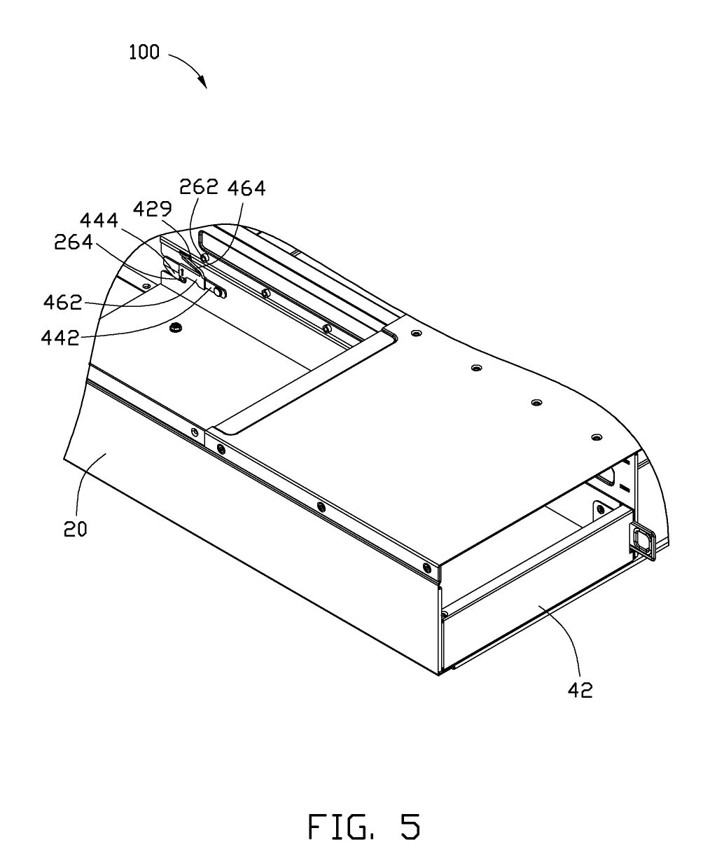

Referring to FIG. 4 and FIG. 5, in assembly of the detachable module 40 to the enclosure 20, the end of the chassis 42 away from the end plate 426 is inserted into the receiving space 29 from the inlet 27. The side plate 424 installed with the latching member 44 slidably abuts the positioning wall 26. A top of the side plate 424 slidably abut bottoms of the guiding pins 262, until the positioning pin 264 of the positioning wall 26 slides into the cutout 427 of the side plate 424. The positioning pin 264 slidably abuts the guiding surface 4441 of the latching member 44, thus rotating up the rotating bar 442. The distal end of the resilient finger 464 abuts the protrusion 429 to be deformed, until the positioning pin 264 passes the guiding surface 4441 to move to the engaging surface 4442 of the latching block 444. The resilient finger 464 is restored to bias the rotating bar 442 to rotate down. The engaging surface 4442 of the latching block 444 blocks the positioning pin 264.

When disassembling the detachable module 40, the latching member 44 is rotated away from the positioning pin 264. The latching block 444 is disengaged from the positioning pin 264. The chassis 42 is removed from the receiving space 29 through the inlet 27. Therefore, the detachable module 40 may be easily separated from the enclosure 20.

It is to be understood, however, that even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

1. An electronic device, comprising:
an enclosure comprising a positioning wall and a positioning pin protruding from a first end of the positioning wall; and
a detachable module comprising a side plate parallel to the positioning wall, a latching member rotatably installed to the side plate, and a resilient member fixed to the latching member and resiliently abutting the side plate;
wherein a latching block extends down from the latching member, the latching block comprises a guiding surface located at a bottom of the latching block and an engaging surface connected to an inner end of the guiding surface, the detachable module is inserted into the enclosure from a second end of the positioning wall, the guiding surface of the latching block slides along the positioning pin, to allow the latching member to rotate and deform the resilient member, until the engaging surface abuts the positioning pin;
wherein the enclosure further comprises a bottom wall and a sidewall perpendicularly extending up from a side of the bottom wall, the positioning wall is mounted on the bottom wall and parallel to the sidewall, the bottom wall, the sidewall, and the positioning wall cooperatively bound a receiving space with an inlet, and the detachable module is inserted into the receiving space from the inlet; and
wherein a plurality of guiding pins protrudes into the receiving space from the positioning wall and is arrayed in one row parallel to the bottom wall, a top of the detachable module slidably abuts against the plurality of guiding pins, and the positioning pin is located between the guiding pins and the bottom wall and away from the inlet.

2. The electronic device of claim 1, wherein the guiding surface is arc-shaped.

3. (canceled)

4. (canceled)

5. The electronic device of claim 1, wherein an end of the side plate of the detachable module defines a cutout for receiving the positioning pin, the latching member is rotatably installed to the end of the side plate.

6. The electronic device of claim 5, wherein a protrusion protrudes from the end of the side plate and is located above the cutout, the resilient member comprises a base fixed to the latching member and a resilient finger portion extending up from the base to abut the protrusion.

7. The electronic device of claim 6, wherein the latching member comprises a rotating bar, an end of the rotating bar away form the latching block is rotatably installed to the side plate, the base is fixed to a middle of the rotating bar.

8. The electronic device of claim 7, wherein the end of the rotating bar defines a rotation hole, the side plate defines a screw hole in a rear end of the cutout, a screw extends through the rotation hole to screw in the screw hole, the latching member is rotated about the screw.
